(19) United States
(12) Patent Application Publication
(10) Pub. No.: US 2021/0373099 A1
(43) Pub. Date: Dec. 2, 2021

(54) METHOD AND SYSTEM FOR MAGNETIC RESONANCE

(71) Applicant: The University of Melbourne, Victoria (AU)

(72) Inventor: Roger John Ordidge, Victoria (AU)

(21) Appl. No.: 16/322,443

(22) PCT Filed: Aug. 2, 2017
(86) PCT No.: PCT/AU2017/050810

§ 371 Date: Jan. 31, 2019

(30) Foreign Application Priority Data
Aug. 2, 2016 (AU) 2016903038

(51) Int. Cl. G01R 33/46; G01R 33/483

(52) U.S. Cl. CPC G01R 33/4616; G01R 33/4833

(57) ABSTRACT

A composite pulse sequence that causes a series of magnetic moment rotations that, in combination, are equivalent to a pulse sequence that would cause a single rotation having a target desired rotation angle α is described. The composite pulse sequence involves a plurality of pulses which each individually have a desired rotation (A°, B° etc) that is less than the target desired rotation α°. The pulses each cause a rotation about respective axes, that may be orthogonal to each other. Slice selection magnetic gradients can be employed to make the component rotations of the composite pulse slice selective.

### FIELD OF THE INVENTION

This invention generally relates to Magnetic Resonance Imaging and spectroscopy. Embodiments may be particularly advantageous in non-uniform magnetic fields.

### BACKGROUND OF THE INVENTION

Magnetic Resonance Imaging (MRI) exploits the nuclear magnetic resonance (NMR) phenomena by combining NMR with gradient magnetic fields to allow cross-sectional slice-selective excitation of nuclei within a subject under examination. In multi-slice imaging, a pulse-sequence of radio-frequency magnetic fields (RF pulse) and associated magnetic field gradients are used with further two dimensional (2D) encoding of the NMR signals to create a 2D image of a portion of the subject. Each slice has an in-slice resolution of around 0.5 mm to 1 mm and slices are spaced around 2 mm apart. A 3D image of the subject is obtained by combining many slices together.

Ideally, in an MR system the RF pulse should deliver a target rotation (a) of the nuclear magnetization vector to provide uniform signal strength over the dimensions of the sample. However, in practice the RF field might typically vary by as much as 50% causing loss of both signal strength and alteration of image contrast by producing magnetization rotations that are far away from the target excitation angle. This variation is typically caused by local magnetic and electrical field effects in the subject, and can lead to spatial inhomogeneity in the local radio-frequency (RF) transverse magnetic field (B1) the nuclei are exposed to. By increasing the static magnetic field strength (B0) an improved signal-to-noise ratio may be obtained along with improved spatial resolution in the images created. However, the above mentioned inhomogeneity in the B1 field is more problematic at B0 fields above 3 T and can lead to imaging artefacts which, in the worst case, are manifested as zero signal in some regions of the image. B1 inhomogeneity effects may also occur at low or medium B0 fields, and when inhomogeneous RF coils such as surface coils are used.

In some cases (e.g. rapid 3D imaging, setting-up patient positioning before a longer relaxation-weighted scan and “freezing” images where the body is in motion) RF pulses are used in rapid MR sequences such as in FLASH and MPRAGE schemes. In FLASH (Fast Low Angle Single Shot) a low spin flip angle)(<90° is combined with rapid repetition of the sequence. In such cases the repetition time (TR) could be between 5 and 50 ms. During the TR interval, the MR signal relaxes back toward equilibrium along the longitudinal (z) axis with an exponential rate constant defined by the T1 value of the tissue being imaged.

With high repetition rates (low TR) a steady-state signal amplitude is quickly formed. The amount of signal measured thus depends on TR and T1. An optimal flip angle, a can be obtained for a particular T1 value, so that the image has 10 to 30% of the S/N ratio and is T1-weighted in its contrast. The optimum signal for a given TR and T1 obtained at an angle α determined by:

cos α=e^{(-TR/T1)}

Such techniques are also susceptible to field inhomogeneities.

Three dimensional MRI also exists. This can be distinguished from multi-slice imaging by the fact that image resolution is the same along all three axes. This property enables any plane orientation to be extracted from a 3D data set and enables surface rendering methods to be used to visualise 3D surfaces of the object, (e.g. the brain surface), in an interactive manner. The MRI method in 3D imaging used does not contain slice selective RF pulses, but excites the whole of the field of view of the RF coil. The third axis of spatial information is encoded using an additional outer loop of incremented phase encoding using the Gz gradient.

However, in 3D MRI a 3-dimensional Fourier Transform is needed to reconstruct the data, and to obtain a 256×256×256 image matrix requires 256×256 experiments. If this were performed with a spin echo sequence with TR=1 second, it would require approximately 20 hours. Therefore, the FLASH sequence may also be used, but without slice selection. Using a TR of 10 milliseconds, the imaging duration is reduced to a more acceptable, 10 minutes.

Nuclear magnetic resonance spectroscopy, similarly tends not be performed in a slice selective manner, but may be used with similar high repetition rate RF pulses.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### SUMMARY OF THE INVENTION

In order to address at least some of the drawbacks noted above, the present inventors have developed a composite pulse sequence that causes a series of magnetic moment rotations that, in combination, are equivalent to a pulse sequence that would cause a single rotation having a target desired rotation angle α. The composite pulse sequence involves a plurality of pulses which each individually have a desired rotation (A°, B° etc) that is less than the target desired rotation α°. The pulses each cause a rotation about respective axes. The rotation axes are preferably orthogonal to each other. Slice selection magnetic gradients can be employed to make the component rotations of the composite pulse slice selective. Optionally phase correction (re-phasing) gradients can also be included in the pulse sequence.

To avoid doubt, the term “subject” is used in the present specification to mean any biological or non-biological entity which is the subject of the MR investigation. In the illustrative embodiments the subject is described in the context of a human patient or an animal subject. However in other embodiments the subject could be a biological or non-biological sample.
In a first aspect the present invention provides a method for use in magnetic resonance imaging or spectroscopy. The method may include:
exposing at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field (B0);
performing a plurality of repeated composite rotations configured to rotate the net magnetisation by a desired angle α°, said composite rotations being repeated with a repetition time of TR, and wherein performing. Each composite rotation can include:
   performing a first rotation by, exposing at least said portion of the subject to a first radio-frequency magnetic field pulse (B1a) to excite nuclei within at least a portion of the subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
performing a second rotation by exposing at least said portion of the subject to a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
wherein A° and B° are less than 90°.
In a second aspect the present invention provides a method of determining operating parameters for an MR system for use in a MR pulse sequence including a plurality of repeated composite rotations which are configured to rotate the net magnetisation by a desired angle α°. The method may include:
   Receiving an input indicating a repetition time (TR) for the pulse sequence;
   Receiving an input indicating at least one subject related imaging parameter representing at least one substance type to be imaged;
   Determining the desired angle α° based on TR and the at least one subject related imaging parameter;
   Determining one or more parameters of the plurality of rotations in the composite rotation so that the composite rotation is configured to rotate the net magnetisation by a desired angle α°.

In a third aspect the present invention provides a magnetic resonance system configured to perform a method according to an embodiment of the first or second aspects described above. Such a system may include:

magnetic field producing means for producing a magnetic field (B0);

radio-frequency magnetic field generating means configured to produce radio-frequency magnetic fields (B1a and B1b); and

positioning means for positioning at least part of a subject to be exposed to the effective magnetic field.
In a fourth aspect the present invention provides a magnetic resonance pulse sequence to be used with a magnetic resonance imaging or spectroscopy system. The system being configured, in use to expose at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field; the MR pulse sequence including:
a plurality of repeated composite rotations configured to rotate the net magnetisation by a desired angle α°, said composite rotations being repeated with a repetition time of TR, wherein each composite rotation includes:
   a first rotation including a first radio-frequency magnetic field pulse (B1a) to excite nuclei within at least a portion of the subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
   a second rotation including a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
   wherein A° and B° are less than 90°.
In a fifth aspect the present invention provides a non-tangible computer readable medium storing instructions thereon which when executed by a data processor associated with an magnetic resonance imaging system or magnetic resonance spectroscopy system cause said system to either:
   generate a MR pulse sequence in accordance with an embodiment of the fourth aspect of the present invention; or
   perform a method according to an embodiment of the first or second aspects of the present invention.

In other aspects of the present invention, there are provided magnetic resonance (MR) pulse sequences to be used with a magnetic resonance system. The pulse sequences may be used by any one of the methods disclosed herein.

The appended claims define additional embodiments and aspects of the present invention.

As used herein, except where the context requires otherwise, the term “comprise” and variations of the term, such as “comprising”, “comprises” and “comprised”, are not intended to exclude further additives, components, integers or steps.

Further aspects of the present invention and further embodiments of the aspects described in the preceding paragraphs will become apparent from the following description, given by way of example and with reference to the accompanying drawings.

### BRIEF DESCRIPTION OF THE DRAWINGS

FIG. 1 is a block diagram of a magnetic resonance imaging system;

FIG. 2a is a vector diagram showing the equilibrium net magnetisation from an ensemble of nuclei in a uniform magnetic field B0;

FIG. 2b illustrates a pair of vector diagrams, the leftmost being a three dimensional diagram, and the rightmost being a projection onto the y-z plane, each a first rotation of the net magnetisation when the ensemble of nuclei are excited by a suitable RF magnetic field;

FIG. 2c illustrates a pair of vector diagrams, the leftmost being a three dimensional diagram, and the rightmost being a projection onto the x-z plane, each showing a second rotation of the net magnetisation when the ensemble of nuclei are excited by a suitable RF magnetic field;

FIG. 3 is a plot of an exemplary MRI pulse sequence;

FIG. 4 illustrates another embodiment of an MRI pulse sequence according to an aspect of the present invention which uses a second slice selective gradient that performs re-phasing of spin vectors as well as slice selection.

FIG. 5 illustrates simulations of the total received signal strength, for a conventional α° degree sinc pulse, and two composite pulse sequences of embodiments of the present invention having different A:B ratios, plotted over a range of RF signal amplitudes.

FIG. 6 is a flowchart illustrating a process for determining operating parameters for an MR system according to a further aspect of the present invention.

### DETAILED DESCRIPTION OF THE EMBODIMENTS

Illustrative embodiments will now by described by way of example only. The examples described will be adapted for two dimensional MRI and thus are slice selective. Some embodiments described herein can be considered as special cases of the methods described in PCT/AU2016/050068 also in the name of The University of Melbourne, the contents of which are incorporated herein by reference for all purposes.

By way of overview, the illustrative embodiments of the pulse sequence can be used on a FLASH sequence and are described for a fixed repetition time (TR) and spin lattice relaxation time (T1), and include two-component composite RF pulses. Each of the two components of the RF pulse may be chosen to cause separate excitation angles (A° and B°) with the magnetization excited first along different, and preferably transverse planes for each rotation (called herein Mx-transverse plane, and the My-transverse plane). In the preferred embodiments, the ratio of the excitation angles)(A°:B° are chosen to produce two complimentary slice shapes that when added together, produce a slice profile defined within the desired region of space, but preferably with a greater tolerance to the overall RF amplitude in that region of space.

The temporal shape (and hence slice shape profile), and gradient magnitudes, for each of the two pulses in the composite pulse may be different to each other. The exact temporal waveforms would be tailored to the T1 values of the tissues being imaged and the TR values using a simple computer algorithm. The computer algorithm simulates the steady-state signal achieved across the selected slice profile by using rotation matrices that describe the evolution of the sample magnetization in the rotating reference frame as defined by the Bloch equations.

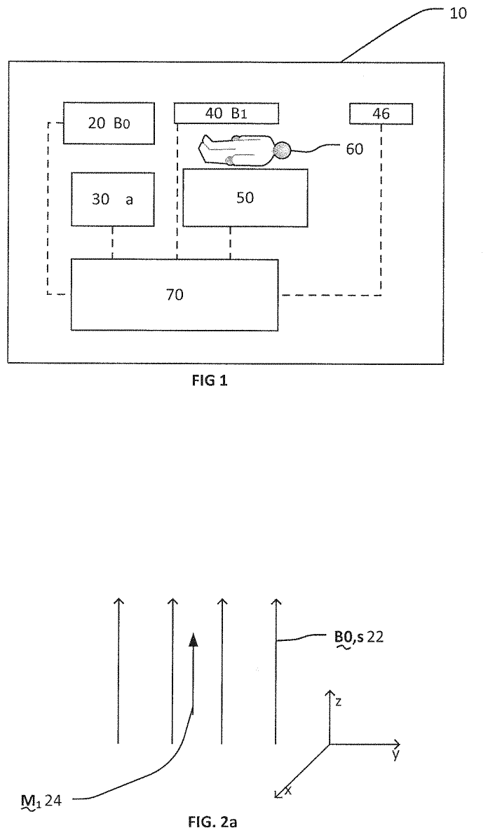

Turning now to the figures, FIG. 1 shows a highly schematic block diagram for a Magnetic Resonance Imaging (MRI) system 10 including:
a magnetic field producing means 20;
a magnetic field gradient producing means 30;
a radio-frequency magnetic field generating means 40;
an RF receiver 46;
a positioning means 50; and
a control unit 70.

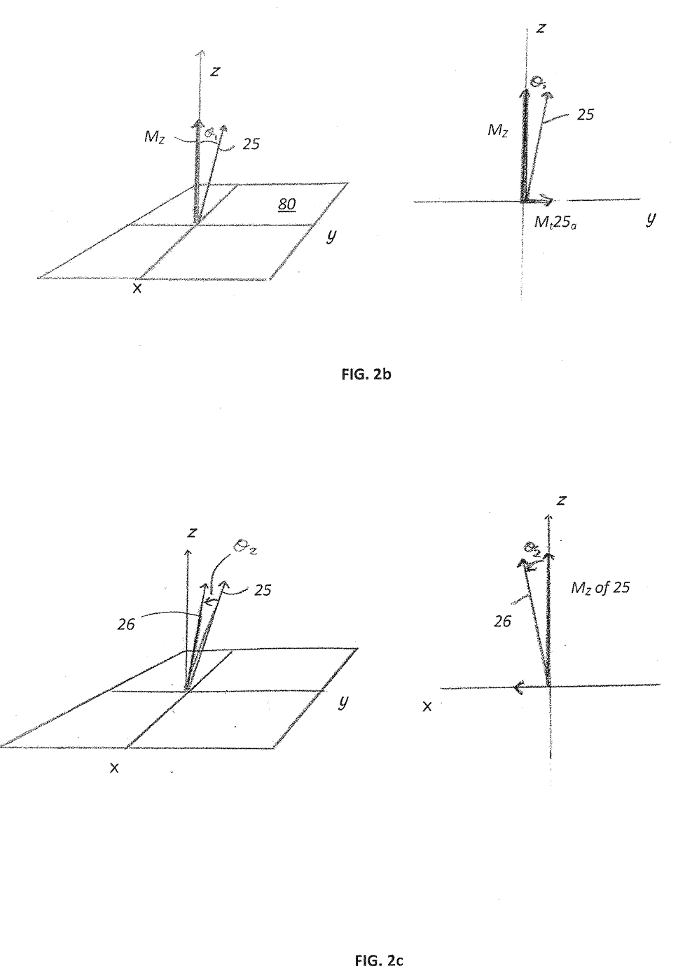

The magnetic field producing means 20 is configured to produce a static uniform magnetic field B0,s 22 aligned to a longitudinal direction along the z-axis (FIG. 2a). A preferred example of the field producing means 20 is a superconducting magnet system.

The magnetic field gradient producing means 30 is configured to produce a magnetic field gradient G. This can be thought of an additional magnetic field that alters the magnetic field B0,s 22 to produce a modified magnetic field B0. The gradient is not strong enough to vary the direction of the field, so B0 is always parallel with B0,s 22 in the longitudinal axis. Therefore it suffices to define B0 in terms of the component in the longitudinal direction and it is unnecessary to refer to it as a vector quantity. It will therefore be referred to as a scalar quantity B0 without loss of generality. As will be discussed further below, the gradient is used for slice selection, but could be omitted if spectroscopy or three dimensional MRI is being performed.

The radio-frequency (RF) magnetic field generating means 40 is configured to produce transversely oriented RF magnetic fields B1a and B1b, i.e. oriented such that they lie in the x-y plane, that oscillate at a radio-frequency corresponding to the Larmor frequency of a nuclei of interest for MRI (typically protons or carbon-13) exposed to the magnetic field B0. The RF magnetic fields may be linearly or circularly polarised depending on the type of RF magnetic field generating means 40 used and have a phase defined by the operator.

The positioning means 50 is for positioning at least part of a subject 60 in the magnetic field B0.

The system also includes a RF receiver 46, such as RF receiver coils, for receiving an MRI signal. In some embodiments, the RF receiver is part of the RF magnetic field generating means 40. The RF receiver is typically only sensitive to RF magnetic fields oriented in the transverse plane.

In some embodiments, the system 10 includes a control unit 70. Control unit 70 is communicatively coupled with the other components (20, 30, 40, 50) of the system 10. Control unit 70 may include a storage means 72 for storing instructions that determine how the control unit 70 controls the other components (20, 30, 40, 50). Instructions include programs for generating MRI pulse sequences that vary the RF magnetic fields B1 and the magnetic field gradient G to selectively excite nuclei in a cross-sectional slice of the subject exposed to the magnetic field B0. By varying the gradients over two dimensions in k-space, the MRI signals can be spatially encoded to produce a 2D raw image (phase encoding, frequency encoding). Using known Fourier transform MRI techniques, the 2D raw image can be converted or transformed into a 2D image of a cross-sectional slice of the subject. Careful selection of pulse sequence parameters can be used to improve image contrast between various compounds or materials within the subject. By taking many 2D images a 3D image of the subject can be obtained.

The magnetic field producing means 20 may either be controlled by the control unit 70 or it may be persistently producing field B0 (as is usually the case for a superconducting magnet system). The magnetic field producing means 20 and magnetic field gradient producing means 30 may also be in communication with the control unit 70 such that the control unit can monitor their status and/or functionality. For example, the control unit 70 may monitor whether the correct magnetic field strength is being produced, either directly through measuring the proton frequency of the signal from water or indirectly by monitoring an electrical characteristic of the field producing means 20 such as power output.

The subject 60 contains an ensemble of nuclei each with a magnetic moment. When at least a portion of the subject 60 (therefore the ensemble of nuclei within the portion) is exposed to the magnetic field B0 it is considered that, statistically, a greater proportion of the nuclei's magnetic moments become aligned with the magnetic field B0. The time-averaged magnetisation of the portion exposed to the magnetic field B0 is, at equilibrium, described by a net magnetisation vector M, 24 parallel to the direction of the magnetic field B0 (FIG. 2a). At the start of an MRI pulse sequence, the magnetisation M is considered to be at equilibrium and oriented as shown in FIG. 2a.

As will be appreciated by the person skilled in the art, exposure of a subject to a magnetic field is not intended to be limited to mean exposure of a surface of the subject, or the near sub-surface, and is intended to include exposing the nuclei within and throughout the subject to said magnetic field. The use of the term is also intended to include the situation where the MRI system has a persistent magnetic field B0 and the subject is introduced into the field.

Rotation of Magnetisation Vector by RF Magnetic Fields

As is known in the art, a transverse RF magnetic field (B1) that is orthogonal to the main magnetic field B0 is typically used to cause rotation of the net magnetisation M, 24 away from the longitudinal axis (z-axis) so that a component of magnetization is created in the transverse plane. This is necessary for the RF receivers to measure a MRI signal. Typically, in a flash sequence a low angle rotation, say between 10° and 30°, is desired.

As illustrated in FIGS. 2b and 2b, in an embodiment of the invention, an MRI pulse sequence with two RF oscillating magnetic fields (B1a and B1b) is used in combination to rotate the magnetisation vector M from its initial alignment in the z-direction away by a desired angle α°.

FIG. 2b shows in its leftmost figure a three dimensional representation of a magnetisation M, and in its rightmost figure a projection of this rotation onto the y-z plane, to aid visualisation. In this example, the first RF magnetic field (B1a) excites the nuclei and causes a first rotation of the magnetisation M about a first axis (which is defined as the x-axis) by a first angle (θ1 equal to A°) towards the y-axis and therefore towards the transverse plane 80. As the magnetisation M is rotated away from its original equilibrium orientation 24 aligned with the z-axis, the rotated magnetization 25 can be considered to consist of a transverse vector component (Mt, 25a) in the x-y plane 80 and a residual vector component (z-component) aligned along the z-axis (Mz, 25b). The z-component Mz may be parallel or anti-parallel to the z-axis depending on the magnitude of the first angle θ1. As the ensemble is still exposed to the magnetic field B0, the transverse component Mt (and therefore the rotated magnetisation, M) precesses about the z-axis at the Larmor frequency. The magnetisation vectors shown in the drawings are drawn in the rotating frame of reference rotating at the Larmor frequency.

The desired first angle of rotation θ1 can be set by choosing an appropriate combination of duration and amplitude of a pulsed RF magnetic field B1a. As noted above, parts of the subject being scanned may affect the local strength of the RF magnetic fields (B1) at particular locations (spatial inhomogeneity) and cause the corresponding rotation angle at said locations to also be affected. This may result in up to a 50% variation in the actual rotation angle compared to the set angle, i.e. for a desired 15° rotation angle, this could result in an actual rotation between 7° and 23°.

The present inventor has identified that by exposing the subject to a second slice-selective RF magnetic field B1b that is configured to rotate the magnetisation about an orthogonal axis in the rotating reference frame (or in the case of circularly polarised RF magnetic fields, that is 90° out of phase with the first RF field B1a), portions of the subject where the rotation angle deviates from the desired angle α° can be further rotated closer to it. This is further explained in an exemplary embodiment with regard to FIG. 2c.

As shown in FIG. 2c, the second RF magnetic field (B1b) excites the ensemble of nuclei to induce a second rotation of the rotated magnetisation M about a second axis, in this example the y-axis (therefore orthogonal to the first axis), by a second angle (θ2 equal to B°) to a second orientation 26.

The second rotation θ2 can be considered as only rotating the residual component of M that remains along the Z axis after the first rotation, i.e Mz 25b. The transverse component Mt 25a is aligned with the y-axis and thus is not displaced by the second rotation.

The second angle θ2 can be selected in the same manner as the first angle. In a preferred embodiment, the second angle θ2 is chosen to match the particular tissue or substance to be imaged. Importantly, the spatial inhomogeneity of the first RF magnetic field does not vary greatly with direction of the applied RF field and therefore will have the same effect on the second RF magnetic field B1b and therefore the corresponding rotation angle.

An advantage of some embodiments is that the resultant rotation caused by the multi-part part rotation is more uniformly close to the desired a rotation over a larger range of non-uniform B1 field conditions, than if only one rotation is performed. In this way, the two part rotation may be seen as being less sensitive to inhomogeneity in the RF magnetic field B 1.

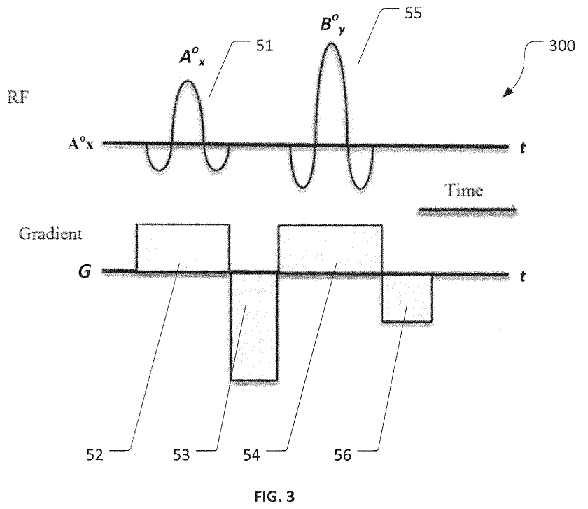

FIG. 3 illustrates an exemplary slice selective composite RF pulse according to an embodiment of the present invention. The composite pulse sequence is intended to be used in a FLASH sequence or similar pulse sequence, which calls for a repeated application of a rotation of the net magnetisation about the y axis by a desired angle α°

The pulse sequence 300 of FIG. 3 generally includes two RF magnetic field pulses with a phase offset of 90° (i.e. which cause rotation of the net magnetisation about orthogonal axes) and with a pulse amplitude A:B of 1:2, (i.e. the rotation angle of the first pulse is half that of the second). In more detail the pulse sequence includes:

a first rotation generated by first RF pulse 51 (B1a), having an amplitude to cause a desired rotation of A° about the x axis. The first rotation is slice selective and thus includes a corresponding first magnetic field gradient 52;

a second rotation, generated by a second RF pulse 55 (B1b) having an amplitude to cause a desired rotation of B° about the y axis. Again the second rotation is slice selective and thus includes a corresponding second magnetic field gradient 54;

one or more phase adjustments; in this case being, a first re-phasing gradient 53 and a second re-phasing magnetic field gradient 56.

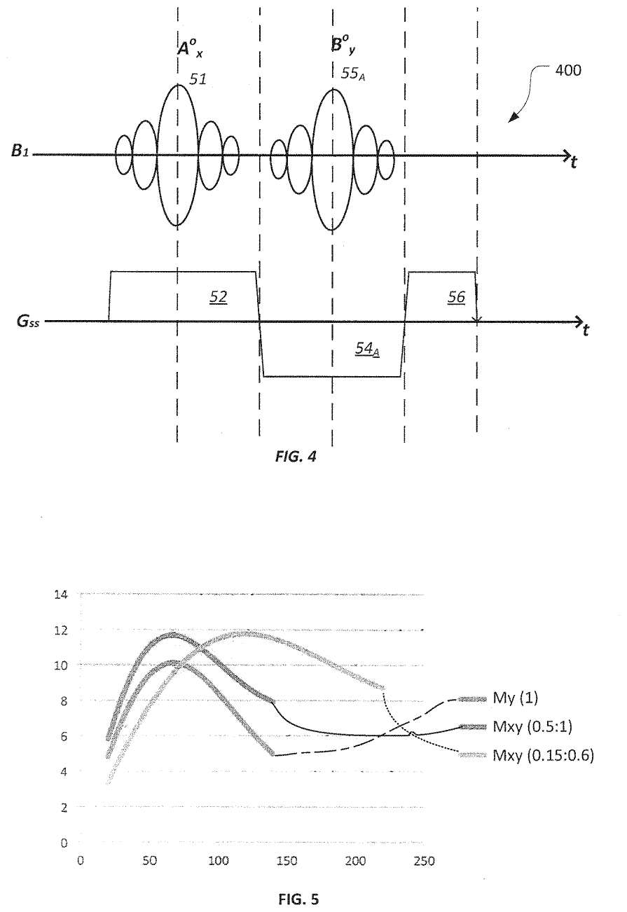

In this example the gradients (52, 54) applied at the time of the B1a and B1b fields have the same amplitude and B1a and B1b overlap in frequencies covered, the same selected slice of the ensemble of nuclei in the subject is excited by both B1a and B1b. As will be seen FIG. 4 shows an alternative approach in which the slice selection gradients provide a magnetic field that changes magnitude in opposite directions, that is one of the slice selection gradients has a positive gradient and the other a negative gradient.

In this example the second rotation angle B° y is twice that of the first angle A° x. This could be achieved if the pulse length of B1b is twice that of B1a, or the amplitude of B1b is doubled that of B1a, or a suitable combination of pulse length and amplitude adjustment is used provided that the same slice is selected. In other embodiments, B1a and B1b are either identical or any other desirable ratio. To avoid doubt B° y could be smaller than A° x.

In practical embodiments, the RF magnetic fields are limited in time, commonly referred to as RF pulses. In preferred embodiments, the RF magnetic field is modulated as a time-limited sinc function. This can be considered a sinc function multiplied by a window function such as a Hamming, rectangular function or any known window function. However any shaped pulse could be selected.

FIG. 4 illustrates another exemplary MRI pulse sequence. This differs from the previous embodiment in that instead of applying a re-phasing gradient (53 in FIG. 3) between the two slice selective rotations, the second gradient selected for the second slice selective rotation is arranged to perform the re-phasing role as described below.

This MRI pulse sequence 400 begins with a first radio-frequency magnetic field pulse (51) and a corresponding first magnetic field gradient 52 that are used to excite nuclei within a part of a subject to perform a first slice-selective rotation. As noted above this first radio-frequency magnetic field pulse rotates a net magnetisation vector, about a first axis (e.g. the x axis) such that a portion of the magnetisation now lies in along the y axis. As with the previous example the first slice selection gradient 52 is a magnetic field that has a magnitude that increases along direction that is transverse to the slice being imaged. For convenience this is deemed to be a positive gradient.

Next a second radio-frequency magnetic field pulse (55A) and corresponding second magnetic field gradient 54A is used to cause a second slice-selective rotation. As with the previous embodiment this pulse and slice selection gradient cooperate to rotate the net magnetisation about a second axis (the y axis in this example). Where this embodiment differs from the previous embodiment, is that the second slice selection magnetic field gradient 54A has a negative gradient compared to the first slice selection gradient 52. That is, the magnetic field caused by the second slice selection gradient 54A decreases along the direction in which the first slice selection gradient 52 increases. This means that as well as enabling slice selection, the gradient 54A causes at least partial re-phasing of the magnetisation vectors that were de-phased by the first slice selective rotation process.

As will be appreciated the first and second positive and negative gradients will need to be created so that the slices formed by each gradient are in registration with each other. This may require the second RF pulse to have a negative frequency offset applied to so that the slice centres align along direction of the B0 field. This allows slices offset from the centre of the magnet to be excited.

Finally, the pulse sequence (400) of FIG. 4 includes final re-phasing magnetic field gradient 56 to correct de-phasing of the magnetisation vectors within the ensemble that are a result of the second slice-selective rotation. Final re-phrasing magnetic field gradient 56 in this case consists of a positive gradient of approximately half the duration of the gradient applied in the previous slice selection gradient segment but equal size.

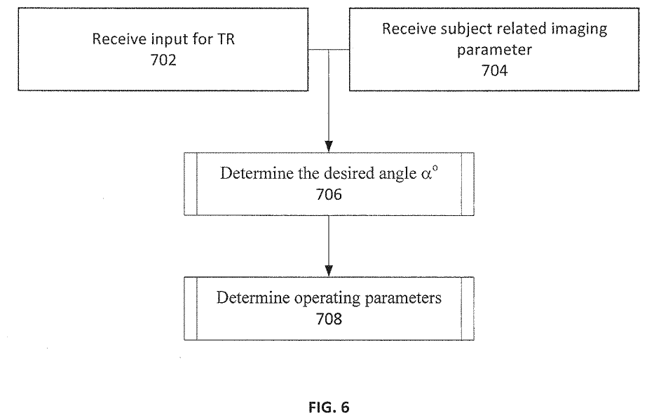

FIG. 5 shows a computer simulation of the steady state Signal strength (Mxy magnetization) vs. RF amplitude of two exemplary embodiments of two-component composite RF pulses (in the amplitude ratio 1:2 and 1:4) compared to a single α pulse (approximately 15°). In this example, T1 of the sample is set at 1100 ms and TR of the pulse sequences is 10 ms. The signal strength in each case is plotted after 20 repetitions of the pulse, to achieve steady state.

All individual pulses (i.e the component pulses of the exemplary composite pulses, and the single α pulse) are sinc pulses.

As can be seen, the signal amplitude for both two component composite pulses varies less over a wide range of RF amplitudes than the single Sinc pulse. The signal strength realised by the composite pulses is postulated to be because of improved slice definition. In the embodiments illustrated, the first pulse in the composite pulse sequence, excites areas with high B1 amplitude (i.e. areas where field inhomogeneity causes a locally high field strength). The second pulse which (in these examples) is stronger (e.g. 2 or 4 times in the examples) targets areas where there is low B1 (i.e. areas where field inhomogeneity causes a locally low field strength) but has a lesser effect on the spins excited by the first pulse (because they have a relatively reduced remaining Mz component). Hence the second pulse can be seen as “filling in” the areas missed (of least affected) by the first pulse.

In order to allow ease of use of the pulse sequences described herein in a FLASH sequence or similar high repetition rate imaging strategy, the inventors have also disclosed a method of determining the operating pulse sequence parameters for use in certain imaging situations. FIG. 6 is a flowchart illustrating a process for determining operating parameters for an MR system according to a further aspect of the present invention. The method includes:
Receiving an input indicating a repetition time (TR) for the pulse sequence (702). In some cases this can include receiving a direct input of a repetition time (TR) for the pulse sequence, or an input from which a repetition time can be determined. For example this could be a total imaging time, the number of images to be captured within the total imaging time, a desired resolution or other suitable input from which TR could be determined.
Receiving an input indicating at least one subject related imaging parameter representing at least one substance type to be imaged (704). A subject related imaging parameter is any parameter that affects the T1 value that the imaging sequence should be optimised for, and from which T1 can be determined. For example this could be a tissue type, mix of tissue types, a direct input of a T1 value; the body part being imaged, a condition/pathology or clinical aspect being investigated, or a known image type to list a few. In the event that the at least one subject related imaging parameter is not a T1 value; the method can thus include determining a corresponding T1 for the imaging sequence. This step could include a measurement step in which the MR system is used to determine T1 relaxation time for the portion of the subject being imaged.
Determining the desired flip angle α° for the pulse sequence (706). This sub process uses the values form steps 702 and 704 to determine the optimum rotation angle for the pulse sequence. In one form the desired angle α° (Ernst Angle) is determined by:

cos α=e^{(-TR/T1)}
Determining one or more parameters of the plurality of rotations in the composite pulse sequence so that the composite rotation is configured to rotate the net magnetisation by a desired angle α° (708). The key parameters to be determined will typically be selected from the following list of parameters:
A:B ratio or A:B:n ratio where n component pulses are used.
The desired rotation angles of the first or second (or subsequent) rotations in the composite pulse sequence.
This can include, determining a desired first rotation angle A° for the first radio-frequency magnetic field pulse (B1a); and a desired second rotation angle B° for a second radio-frequency magnetic field pulse (B1b). As will be appreciated, for pulse sequences with more than two component rotations, additional rotation angles will need to be determined also.
The selection of the A:B ratio and rotation angles for a given a rotation can be performed using several methods. In some embodiments it may include selecting pre-computed values for said parameters, from a database or look-up table. In other embodiments the method can include performing a simulation of an MR pulse sequence using at least some of the received data, and possibly other relevant data, such as a Specific Absorption Rate for the portion of the subject being imaged or a B1 uniformity map, showing the range of B1 fields over which a correction is required.
In some instances a simulation can be used to assist in determining the a preferred A:B ratio. For example a plot as shown in FIG. 5 (Total received signal vs. RF amplitude) can be generated and visualized using a Bloch Equation Simulator, such as the simulator for MatLab, available from Stanford University at mrsrl.stanford.edu/˜brian/bloch/.
Such a simulation can be run and visualised for different A:B ratios and a pulse sequence chosen that is optimised for the particular imaging scenario selected. To give an example, if “α°” is determined to be 20°, then optimum flip angles for a 1-2 pulse could be 13° and 27° (e.g. +/−⅓rd of 20°) to obtain an approximate two-fold insensitivity to B1 differences. As described above the lower RF pulse angle 13° preferentially excites tissue in areas of high B1 field (reaching the optimal steady state condition) whereas the larger RF pulse angle 20° performs closer to the optimum for tissue in a low B1 field.
Operator skill may also play a factor in determining suitable values. For example, it may be that the operator choose a pulse sequence with more signal, but accept a narrower range of B1 correction. Alternatively B1 correction might be more desirable in some cases. However in other circumstances, the optimization could take into account tissue contrast between one tissue type for which the pulse sequence is optimized and surrounding tissue. In such cases the tissue contrast is produced by a mix of choice of TR and the flip angles of the two RF pulses, and the T1 value for surrounding tissue.
Such parameters, once chosen or optimized, could be stored in a look up table or database for use in future scans of similar body sections with similar pathologies.

Once the parameters have been determined the MR system can be configured to use these parameters in the conventional manner to perform an imaging sequence using the determined parameters. The method described in connection with the present aspect of the invention can be implemented in a variety of ways, for example it may be implemented in software running on the control unit 70 of the MR system. It could be implemented by a separate computer system and the parameters either manually transferred to the control unit 70, or transferred thereto via a communications network or other data transfer interface.

1. A method for use in magnetic resonance imaging or spectroscopy, including:
exposing at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field (B0);
performing a plurality of repeated composite rotations configured to rotate the net magnetisation by a desired angle α°, said composite rotations being repeated with a repetition time of TR, and wherein performing each composite rotation includes:
performing a first rotation by:
exposing at least said portion of the subject to a first radio-frequency magnetic field pulse (B1a) to excite nuclei within at least a portion of the subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
performing a second rotation by:
exposing at least said portion of the subject to a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
wherein A° and B° are less than 90°.

2. The method of claim 1, wherein the first axis and the second axis lie in a transverse plane orthogonal to the magnetic field (B0).

3. The method of claim 2 wherein the first axis and second axis are orthogonal to each other in a rotating frame of reference about the longitudinal direction.

4. The method of any one of the preceding claims, wherein A° and B° are equal.

5. The method of any one of the preceding claims, wherein A° and B° are not equal.

6. The method of claim 5, wherein A° is less than B°.

7. The method of claim 5, wherein A° is greater than B°

8. The method as claimed in any one of the preceding claims wherein one or both of A° and B° are less than 60°.

9. The method as claimed in any one of the preceding claims wherein one or both of A° and B° are less than 45°.

10. The method as claimed in any one of the preceding claims wherein one or both of A° and B° are more than 30°.

11. The method as claimed in any one of the preceding claims wherein one or both of A° and B° are more than 2°.

12. The method as claimed in any one of the preceding claims wherein one or both of A° and B° are more than 5°.

13. The method as claimed in any one of the preceding claims wherein one or both of A° and B° are more than 10°.

14. The method as claimed in any one of the preceding claims wherein the ratio of either of A°:B° or B°:A° is greater than or equal to 1:1.5

15. The method as claimed in any one of the preceding claims wherein the ratio of either of A°:B° or B°:A° is greater than or equal to 1:2

16. The method as claimed in any one of the preceding claims wherein the ratio of either of A°:B° or B°:A° is greater than or equal to 1:4

17. The method as claimed in any one of the preceding claims, which is adapted for use in magnetic resonance imaging wherein the repeated composite rotations are slice selective.

18. The method as claimed in claim 17 which further includes applying a first slice selection gradient, comprising a magnetic field gradient corresponding to the first radio-frequency magnetic field pulse (B1a) to make it slice selective.

19. The method as claimed in claim 17 or 18 which further includes applying a second slice selection gradient comprising a magnetic field gradient corresponding to the second radio-frequency magnetic field pulse (B1b) to make it slice selective.

20. The method as claimed in any one of the preceding claims, wherein performing each composite rotation further includes exposing at least said portion of the subject to at least one phase adjustment magnetic field gradient to adjust the relative phasing of the magnetisation vectors within the ensemble, either before, during or after one or more of the first or second rotations.

21. The method of any one of claim 20 wherein a re-phasing gradient is applied after the first rotation.

22. The method of claim 21 wherein the second slice selection gradient comprises a re-phasing gradient that is configured to adjust the relative phasing of the magnetisation vectors within the ensemble after the first rotation.

23. The method of any one of claim 21 or 22 wherein a re-phasing gradient is applied after the second rotation.

24. The method of any one of the preceding claims wherein performing the composite rotation includes:
exposing at least said portion of the subject to a further radio-frequency magnetic field pulse (B1cᵢ) and to excite nuclei within the portion of the subject, the further radio-frequency magnetic field pulse being configured to rotate the net magnetisation about a further axis by a further angle Cᵢ°.

25. The method according to any one of the previous claims, wherein the magnetic field (B0) has a magnitude of at least 1.5 T.

26. The method of any one of the preceding claims wherein the repetition time TR is between 1 ms and 150 ms.

27. The method of any one of the preceding claims wherein the duration of either of the first radio-frequency magnetic field pulse (B1a) and the second radio-frequency magnetic field pulse (B1b) is between 0.5 ms and 5 ms

28. A method of determining operating parameters for an MR system for use in a MR pulse sequence including a plurality of repeated composite rotations which are configured to rotate the net magnetisation by a desired angle α°, the method including:
Receiving an input indicating a repetition time (TR) for the pulse sequence;
Receiving an input indicating at least one subject related imaging parameter representing at least one substance type to be imaged;
Determining the desired angle α° based on TR and the at least one subject related imaging parameter;
Determining one or more parameters of the plurality of rotations in the composite rotation so that the composite rotation is configured to rotate the net magnetisation by a desired angle α°.

29. The method of claim 28 wherein determining one or more parameters of the plurality of rotations in the composite rotation so that the composite rotation is configured to rotate the net magnetisation by a desired angle α° includes:
Determining a desired first rotation angle A° for a first radio-frequency magnetic field pulse (B1a); and
Determining a desired second rotation angle B° for a second radio-frequency magnetic field pulse (B1b),
wherein A° and B° are less than 90°.

30. A method as claimed in any one of claims 28 and 29 wherein the at least one subject related imaging parameter is any one or more of:
Tissue type, T1 value for one or more tissue types, T1 value for one or more material types; Body part being imaged, condition being investigated, image type, a representative T1 value for a plurality of materials or tissue types contained in the subject.

31. The method of claim 30 which further includes, in the event that the at least one subject related imaging parameter is not a T1 value; determining a corresponding T1 value.

32. The method of any one of claims 28 to 31 wherein an input indicating a repetition time (TR) for the pulse sequence can include an input from which a repetition time can be determined.

33. The method of claim 32 wherein the input indicating a repetition time is a total imaging time and/or a total number of composite pulses to apply.

34. The method of any one of claims 28 to 33 wherein the desired angle α° is determined by:
cos α=e^{(-TR/T1)}

35. The method as claimed in any one of claims 28 to 34 wherein determining one or more parameters of the plurality of rotations in the composite rotation so that the composite rotation is configured to rotate the net magnetisation by a desired angle α° includes selecting pre-computed values for said parameters.

36. The method as claimed in any one of claims 28 to 34 wherein determining one or more parameters of the plurality of rotations in the composite rotation so that the composite rotation is configured to rotate the net magnetisation by a desired angle α° includes performing one or more simulations of an MR pulse sequence using one or more of:
the input indicating a repetition time (TR) for the pulse sequence;
the input indicating at least one subject related imaging parameters;
the desired angle α°
a Specific Absorption Rate for the portion of the subject; and
selecting said parameter(s) based on said simulation(s).

37. A magnetic resonance system including:
magnetic field producing means for producing a magnetic field (B0);
radio-frequency magnetic field generating means configured to produce radio-frequency magnetic fields (B1a and B1b); and
positioning means for positioning at least part of a subject to be exposed to the effective magnetic field;
the system being configured to perform a method as claimed in any one of the preceding claims.

38. A magnetic resonance system including:
magnetic field producing means for producing a magnetic field (B0);
radio-frequency magnetic field generating means configured to produce radio-frequency magnetic fields (B1a and B1b); and
positioning means for positioning at least part of a subject to be exposed to the effective magnetic field;
said system being configured to operate in accordance with the parameters determined using a method as claimed in any one of claims 27 to 36.

39. The magnetic resonance system as claimed in claim 38 which includes a data processing system configured to perform the method of any one of claims 27 to 36.

40. The magnetic resonance system as claimed in any one of claims 37 to 39 which further includes a magnetic field gradient producing means configured to produce magnetic field gradients to alter the magnetic field B0 and produce an effective magnetic field, to enable slice selective imaging.

41. A magnetic resonance pulse sequence to be used with a magnetic resonance imaging or spectroscopy system, said system being configured, in use to expose at least a portion of a subject to a longitudinal magnetic field (B0) such that a net magnetisation vector representing a resultant magnetisation of the nuclear magnetic moments of an ensemble of nuclei in the portion of the subject, is longitudinally aligned with the magnetic field; the MR pulse sequence including:
a plurality of repeated composite rotations configured to rotate the net magnetisation by a desired angle α°, said composite rotations being repeated with a repetition time of TR, wherein each composite rotation includes:
a first rotation including a first radio-frequency magnetic field pulse (B1a) to excite nuclei within at least a portion of the subject, the first radio-frequency magnetic field pulse being configured to rotate the net magnetisation about a first axis by a first angle A° such that a first component of the net magnetisation lies in a first plane including the first axis and a second component of the net magnetisation remains aligned with the magnetic field (B0);
a second rotation including a second radio-frequency magnetic field pulse (B1b) to excite nuclei within the portion of the subject, the second radio-frequency magnetic field pulse being configured to rotate the net magnetisation about a second axis by a second angle B° such that at least a portion of the net magnetisation that remained aligned with the magnetic field (B0) after the first rotation lies in a plane including the second axis of rotation; and
wherein A° and B° are less than 90°.

42. A magnetic resonance pulse sequence of claim 41, wherein the first axis and the second axis lie in a transverse plane orthogonal to the magnetic field (B0).

43. A magnetic resonance pulse sequence of 42 wherein the first axis and second axis are orthogonal to each other in a rotating frame of reference about the longitudinal direction.

44. A magnetic resonance pulse sequence of any one of claims 41 to 43, wherein A° and B° are equal.

45. A magnetic resonance pulse sequence of any one of claims 41 to 44, wherein A° and B° are not equal.

46. A magnetic resonance pulse sequence of any one of claims 41 to 45, wherein A° is less than B°.

47. A magnetic resonance pulse sequence of any one of claims 41 to 45, wherein A° is greater than B°

48. A magnetic resonance pulse sequence of any one of claims 41 to 47 wherein one or both of A° and B° are less than 60°.

49. A magnetic resonance pulse sequence of any one of claims 41 to 48 wherein one or both of A° and B° are less than 45°.

50. A magnetic resonance pulse sequence of any one of claims 41 to 49 wherein one or both of A° and B° are more than 30°.

51. A magnetic resonance pulse sequence of any one of claims 41 to 50 wherein one or both of A° and B° are more than 2°.

52. A magnetic resonance pulse sequence of any one of claims 41 to 51 wherein one or both of A° and B° are more than 5°.

53. A magnetic resonance pulse sequence of any one of claims 41 to 52 wherein one or both of A° and B° are more than 10°.

54. A magnetic resonance pulse sequence of any one of claims 41 to 43 wherein the ratio of either of A°:B° or B°:A° is greater than or equal to 1:1.5

55. A magnetic resonance pulse sequence of any one of claims 41 to 54 wherein the ratio of either of A°:B° or B°:A° is greater than or equal to 1:2

56. A magnetic resonance pulse sequence of any one of claims 41 to 55 wherein the ratio of either of A°:B° or B°:A° is greater than or equal to 1:4

57. A magnetic resonance pulse sequence of any one of claims 41 to 56, which is adapted for use in magnetic resonance imaging wherein the repeated composite rotations are slice selective.

58. A magnetic resonance pulse sequence of claim 57 which further includes a first slice selection gradient, comprising a magnetic field gradient corresponding to the first radio-frequency magnetic field pulse (B1a) to make it slice selective.

59. A magnetic resonance pulse sequence of any one of claim 57 or 58 which further includes a second slice selection gradient comprising a magnetic field gradient corresponding to the second radio-frequency magnetic field pulse (B1b) to make it slice selective.

60. A magnetic resonance pulse sequence of any one of claims 41 to 59, which further includes at least one phase adjustment magnetic field gradient to adjust the relative phasing of the magnetisation vectors within the ensemble, either before, during or after one or more of the first or second rotations.

61. A magnetic resonance pulse sequence of claim 60 wherein a re-phasing gradient is applied after the first rotation.

62. A magnetic resonance pulse sequence of claim 61 wherein the second slice selection gradient comprises a re-phasing gradient that is configured to adjust the relative phasing of the magnetisation vectors within the ensemble after the first rotation.

63. A magnetic resonance pulse sequence of any one of claim 61 or 62 wherein a re-phasing gradient is applied after the second rotation.

64. A magnetic resonance pulse sequence of any one of claims 41 to 63 which includes:
a further radio-frequency magnetic field pulse (B1cᵢ) to excite nuclei within the portion of the subject, the further radio-frequency magnetic field pulse being configured to rotate the net magnetisation about a further axis by a further angle Cᵢ°.

65. A magnetic resonance pulse sequence of any one of claims 41 to 64, wherein the magnetic field (B0) has a magnitude of at least 1.5 T.

66. A magnetic resonance pulse sequence of any one of claims 41 to 65 wherein the repetition time TR is between 1 ms and 150 ms.

67. A magnetic resonance pulse sequence of any one of claims 41 to 66 wherein the duration of either of the first radio-frequency magnetic field pulse (B1a) and the second radio-frequency magnetic field pulse (B1b) is between 0.5 ms and 5 ms

68. A non-transient computer readable medium storing instructions thereon which when executed by a data processor associated with an magnetic resonance imaging system or magnetic resonance spectroscopy system cause said system to perform one or more of the following:
generate a MR pulse sequence of any one of claims 41 to 67; or
perform a method as claimed in any one of claims 1 to 40.

69. A method of operating a magnetic resonance (MR) system, said method comprising;
Determining operating parameters according to any one of claims 28 to 36,
Generating one or more control signals to cause the MR system to generate an MR pulse sequence in accordance with said operating parameters.
